(19) United States
(12) Patent Application Publication
(10) Pub. No.: US 2014/0242294 A1
(43) Pub. Date: Aug. 28, 2014

(54) METHOD OF MANUFACTURING A RESISTIVE TOUCH SENSOR CIRCUIT BY FLEXOGRAPHIC PRINTING

(71) Applicant: UNIPIXEL DISPLAYS, INC., The Woodlands, TX (US)

(72) Inventors: Robert J. Petcavich, The Woodlands, TX (US); Ed S. Ramakrishnan, The Woodlands, TX (US); Daniel K. Van Ostrand, The Woodlands, TX (US); Reed Killion, The Woodlands, TX (US); Kevin J. Derichs, The Woodlands, TX (US)

(73) Assignee: UNIPIXEL DISPLAYS, INC., The Woodlands, TX (US)

(21) Appl. No.: 14/354,492

(22) PCT Filed: Oct. 24, 2012
(86) PCT No.: PCT/US2012/061575

§ 371 Date: Apr. 25, 2014

Related U.S. Application Data
(60) Provisional application No. 61/551,109, filed on Oct. 25, 2011.

(51) Int. Cl. H05K 3/46

(52) U.S. Cl. CPC H05K 3/4664
USPC 427/534; 427/97.4; 427/560

(57) ABSTRACT

Method of manufacturing a resistive touch sensor circuit using a roll to roll process to print microscopic patterns on a single side of at least one flexible dielectric substrate using a plurality of flexo-masters to print the microscopic patterns which are then plated to form conductive microscopic patterns.

### CROSS-REFERENCE TO RELATED APPLICATION

The present application claims priority to U.S. Provisional Patent Application No. 61/551,109, filed on Oct. 25, 2011 (Attorney Docket No. 2911-02300); which is hereby incorporated herein by reference.

### BACKGROUND

This disclosure relates generally to flexible printed electronics, specifically to the fabrication of touch sensor circuits that may be formed by high resolution lines. A touch sensor manufacturing process may comprise a thin flexible substrate sheet that is transferred by a roll-to-toll manufacturing method. The roll-to-toll method transfers the substrate from a feed reel into a washing system, which may be for example a plasma cleaning process, an elastomeric cleaning process, or an ultrasonic cleaning process. Subsequent to the wash cycle, there may be thin film deposition In a chemical or physical vapor deposition chamber. During this film deposition process, transparent conductive material, for example Indium Tin Oxide (ITO) is deposited on a surface of the flexible substrate. The substrate then may be cured by method such as heating by infrared heater, ultraviolet heater, or a convection heater, and a drying step may be performed prior to winding up the substrate on a take up reel. Multiple lamination steps may be performed, for example, lamination, etching, printing, and assembly may be required to form a complete touch sensor circuit.

In accordance with various embodiments, a method comprises cleaning a flexible transparent substrate, forming a microscopic pattern on the substrate, creating a conductive pattern by electrolessly plating the microscopic pattern of the substrate, printing spacer dots onto the substrate, and assembling a resistive touch sensor circuit.

### SUMMARY

In an embodiment, a method for manufacturing a resistive touch sensor circuit comprising: creating a first circuit component, wherein creating the first circuit component comprises: printing, by a flexographic printing process using a first master plate and a first ink, a first pattern on a first side of the first substrate; curing the substrate; depositing, by an electroless plating process, a first conductive material on the first side of the first substrate; printing, by the flexographic printing process using a second master plate and a second ink, a first plurality of spacer microstructures; and subsequently curing the substrate. The embodiment further comprising creating a second component comprising: printing, by the flexographic printing process using a third master plate and a third ink, a second pattern on a first side of the second substrate; curing the substrate; depositing, by the electroless plating process, a second conductive material on the first side of the second substrate; printing, by the flexographic printing process using a fourth master plate and a fourth ink, a second plurality of spacer microstructures; and subsequently curing the substrate.

In another embodiment, a method for manufacturing a resistive touch sensor circuit comprising: cleaning a substrate, wherein a plane of the substrate comprises an X and a Y axis; printing, by a flexographic process using a first master plate and a first ink, a first pattern on a first side of the substrate, printing, by a flexographic process using a second master plate and the ink, a second pattern on the first side of the substrate. The embodiment further comprising, curing the substrate; depositing, by an electroless plating process, a conductive material on the first side of the substrate, printing, by a flexographic process using a third master plate and a second ink, a plurality of spacer microstructures on the same area of the substrate where the first pattern was printed; subsequently, curing the substrate.

In an alternate embodiment, a method for manufacturing a resistive touch sensor circuit comprising: printing, using a first master plate and a first ink, a first pattern on a first side of the substrate; printing, by a flexographic printing process using a second master plate and a second ink, a second pattern on the first side of the substrate, wherein the first and the second patterns are printed adjacent to each other along a surface plane of the substrate; curing the substrate; depositing, by an electroless plating process, a conductive material on the first, patterned side of the substrate.

### BRIEF DESCRIPTION OF THE DRAWINGS

For a detailed description of exemplary embodiments of the invention, reference will now be made to the accompanying drawings in which:

FIGS. 1A-1C are illustrations of flexo-master embodiments

FIG. 2A-2B are illustrations of patterned flexo-masters.

FIG. 3A-3B are an isometric view and a cross-sectional view of a resistive touch sensor.

FIG. 4 is an embodiment of a method of manufacturing a resistive touch sensor.

FIGS. 5A-5B are embodiments of methods of precision ink metering systems.

FIGS. 6A-6B are illustrations of a top view of a printed touch sensor circuit.

FIG. 7 is a flowchart of an embodiment of a method of manufacturing a touch sensor circuit.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Disclosed herein are embodiments of a system and a method to fabricate a resistive flexible touch sensor (FTS) circuit by, for example, a roll-to-roll manufacturing process. A plurality of master plates may be fabricated using thermal imaging of selected designs in order print high resolution conductive lines on a substrate. A first pattern may be printed using a first roll on a first side of the substrate, and a second pattern may be printed using a second roll on a second side of the substrate. Electroless plating may be used during the plating process. While electroless plating may be more time consuming than other methods, it may be better for small, complicated, or intricate geometries. The FTS may comprise a plurality of thin flexible electrodes in communication with a dielectric layer. An extended tail comprising electrical leads may be attached to the electrodes and there may be an electrical connector in electrical communication with the leads. The roll-to-roll process refers to the fact that the flexible substrate is loaded on to a first roll, which may also be referred to as an unwinding roll, to feed it into the system where the fabrication process occurs, and then unloaded on to a second roll, which may also be referred to as a winding roll, when the process is complete.

Touch sensors may be manufactured using a thin flexible substrate transferred via a known roll-to-roll handling method. The substrates is transferred into a washing system that may comprise a process such as plasma cleaning, elastomeric cleaning, ultrasonic cleaning process, etc. The washing cycle may be followed by thin film deposition in physical or chemical vapor deposition vacuum chamber. In this thin film deposition step, which may be referred to as a printing step, a transparent conductive material, such as Indium Tin Oxide (ITO), is deposited on at least one surface of the substrate. In some embodiments, suitable materials for the conductive lines may include copper (Cu), silver (Ag), gold (Au), nickel (Ni), tin (Sn) and Palladium (Pd) among others. Depending on the resistivity of the materials used for the circuit, it may have different response times and power requirements. The deposited layer of conductive material may have a resistance in a range of 0.005 micro-ohms to 500 ohms per square, a physical thickness of 100 nm to 5 microns and a width of 1 micron to 50 microns or more. In some embodiments, the printed substrate may have anti-glare coating or diffuser surface coating applied by spray deposition or wet chemical deposition. The substrate may be cured by, for example, heating by infrared heater, an ultraviolet heater convection heater or the like. This process may be repeated and several steps of lamination, etching, printing and assembly may be needed to complete the touch sensor circuit.

The pattern printed may be a high resolution conductive pattern comprising a plurality of lines. In some embodiments, these lines may be microscopic in size. The difficulty of printing a pattern may increase as the line size decreases and the complexity of the pattern geometry increases. The ink used to print features of varying sizes and geometries may also vary, some ink compositions may be more appropriate to larger, simple features and some more appropriate for smaller, more intricate geometries.

In an embodiment, there may be multiple printing stations used to form a pattern. These stations may be limited by the amount of ink that can be transferred on an anilox roll. In some embodiments, there may be dedicated stations to print certain features that may run across multiple product lines or applications, these dedicates stations may, in some cases, use the same ink for every printing job or may be standard features common across several products or product lines which can then be run in series without having to change out the roll. The cell volume of an anilox roll or rolls used in the transfer process, which may vary from 0.5-30 BCM (billion cubic microns) in some embodiments and 9-20 BCM in others, may depend on the type of ink being transferred. The type of ink used to print all or part of a pattern may depend on several factors, including the cross-sectional shape of the lines, line thickness, line width, line length, line connectivity, and overall pattern geometry. In addition to the printing process, at least one curing process may be performed on a printed substrate in order to achieve the desired feature height.

Flexography is a form of a rotary web letterpress where relief plates are mounted on to a printing cylinder, for example, with double-sided adhesive. These relief plates, which may also be referred to as a master plate or a flexoplate, may be used in conjunction with fast drying, low viscosity solvent, and ink fed from anilox or other two roller inking system. The anilox roll may be a cylinder used to provide a measured amount of ink to a printing plate. The ink may be, for example, water-based or ultraviolet (UV)-curable inks. In one example, a first roller transfers ink from an ink pan or a metering system to a meter roller or anilox roll. The ink is metered to a uniform thickness when it is transferred from the anilox roller to a plate cylinder. When the substrate moves through the roll-to-roll handling system from the plate cylinder to the impression cylinder, the impression cylinder applies pressure to the plate cylinder which transfers the image on to the relief plate to the substrate. In some embodiments, there may be a fountain roller instead of the plate cylinder and a doctor blade may be used to improve the distribution of ink across the roller.

Flexographic plates may be made from, for example, plastic, rubber, or a photopolymer which may also be referred to as a UV-sensitive polymer. The plates may be made by laser engraving, photomechanical, or photochemical methods. The plates may be purchased or made in accordance with any known method. The preferred flexographic process may be set up as a stack type where one or more stacks of printing stations are arranged vertically on each side of the press frame and each stack has its own plate cylinder which prints using one type of ink and the setup may allow for printing on one or both sides of a substrate. In another embodiment, a central impression cylinder may be used which uses a single impression cylinder mounted in the press frame. As the substrate enters the press, it is in contact with the impression cylinder and the appropriate pattern is printed. Alternatively, an inline flexographic printing process may be utilized in which the printing stations are arranged in a horizontal line and are driven by a common line shaft. In this example, the printing stations may be coupled to curing stations, cutters, folders, or other post-printing processing equipment. Other configurations of the flexo-graphic process may be utilized as well.

In an embodiment, flexoplate sleeves may be used, for example, in an in-the-round (ITR) imaging process. In an ITR process, the photopolymer plate material is processed on a sleeve that will be loaded on to the press, in contrast with the method discussed above where a flat plate may be mounted to a printing cylinder, which may also be referred to as a conventional plate cylinder. The flexo-sleeve may be a continuous sleeve of a photopolymer with a laser ablation mask coating disposed on a surface. In another example, individual pieces of photopolymer may be mounted on a base sleeve with tape and then imaged and processed in the same manner as the sleeve with the laser ablation mask discussed above. Flexo-sleeves may be used in several ways, for example, as carrier rolls for imaged, flat, plates mounted on the surface of the carrier rolls, or as sleeve surfaces that have been directly engraved (in-the-round) with an image. In the example where a sleeve acts solely as a carrier role, printing plates with engraved images may be mounted to the sleeves, which are then installed into the print stations on cylinders. These pre-mounted plates may reduce changeover time since the sleeves can be stored with the plates already mounted to the sleeves. Sleeves are made from various materials, including thermoplastic composites, thermoset composites, and nickel, and may or may not be reinforced with fiber to resist cracking and splitting. Long-run, reusable sleeves that incorporate a foam or cushion base are used for very high-quality printing. In some embodiments, disposable “thin” sleeves, without foam or cushioning, may be used.

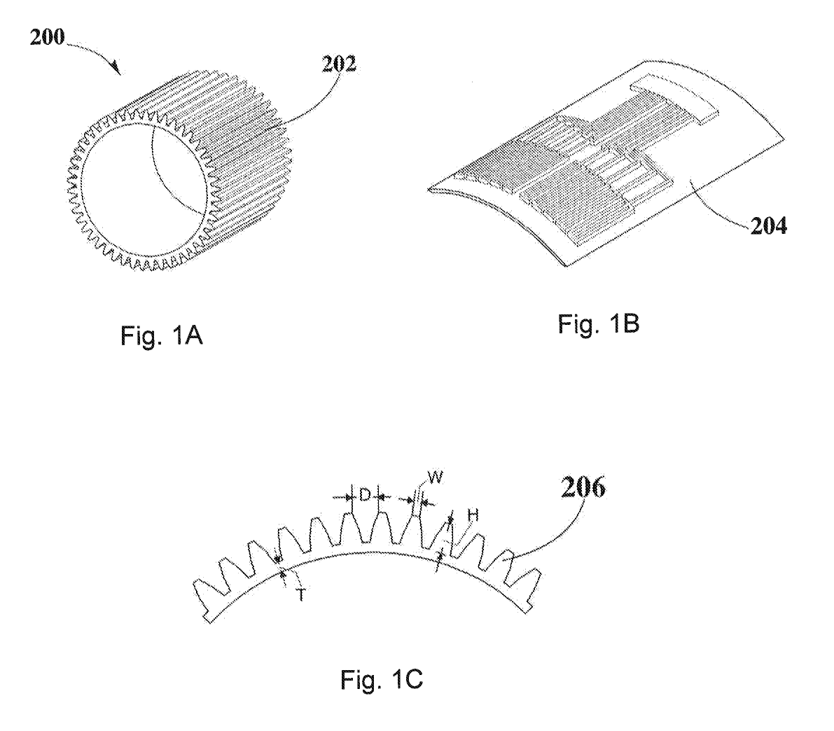

FIGS. 1A-1C are illustrations of flexo-master embodiments at block 200. As noted above, the terms “master plate” and “flexo-master” may be used interchangeably. FIG. 1A displays isometric views of two flexo-masters (upper images), straight lines flexo-master at block 202 which is cylindrical. FIG. 1B depicts an isometric view of an embodiment of a circuit pattern flexo-master at block 204. FIG. 1C depicts a cross sectional view at block 206 of a portion of straight lines flexo-master at block 202 as shown in FIG. 1A. FIG. 1C also depicts “W” which is the width of the flexo-master protrusions, “D,” is the distance between the center points of the protrusions 206 and “H” is the height of the protrusions. The cross-section of the protrusions 206 could be, for example, rectangular, square, half-circles, trapezoids, or other geometries. In an embodiment (not pictured), one or all of D, W, and H may the same or similar measurements across the flexo-master. In another embodiment (not pictured), one or all of D, W, and H may be different measurements across the flexo-master. In an embodiment (not pictured) width W of flexo-master protrusions is between 3 and 5 microns, distance D between adjacent protrusions 1 and 5 mm, height H of the protrusions may vary from 3 to 4 microns and thickness T of the protrusions is between 1.67 and 1.85 mm. The pattern may be configured as to produce a printed pattern with line thickness from 1 micron-20 microns or greater. In an embodiment, printing may be done on one side of a substrate, for example, using one roll comprising both patterns, or by two rolls each comprising one pattern, and that substrate may be subsequently cut and assembled. In an alternate embodiment, both sides of a substrate may be printed, for example, using two different print stations and two different flexo-masters. Flexo-masters may be used, for example, because printing cylinders may be expensive and hard to change out, which would make the cylinders efficient for high-volume printing but may not make that system desirable for small batches or unique configurations. Changeovers may be costly due to the time involved. In contrast, flexographic printing may mean that ultraviolet exposure can be used on the photo plates to make new plates that may take as little as an hour to manufacture. In an embodiment, using the appropriate ink with these flexo-masters may allow the ink to be loaded from, for example, a reservoir or a pan in a more controlled fashion wherein the pressure and surface energy during ink transfer may be able to be controlled. The ink used for the printing process may need to have properties such as adhesion, UV-curability, and may comprise particles, modifiers, or dispersants so that the ink stays in place when printed and does not run, smudge, or otherwise deform from the printed pattern. Further, the ink may be formulated or chosen so that the features formed by the ink join together smoothly and in the correct geometry to form the desired features. The ink may comprise a catalyst that is conducive to plating, for example, electroless plating. A plating catalyst as disclosed here enables a chemical reaction between the ink and the conductive material during the plating process. Each pattern may, for example, be made using a recipe wherein the recipe comprises at least one flexo-master and at least one type of ink. Different resolution lines, different size lines, and different geometries, for example may require different recipes.

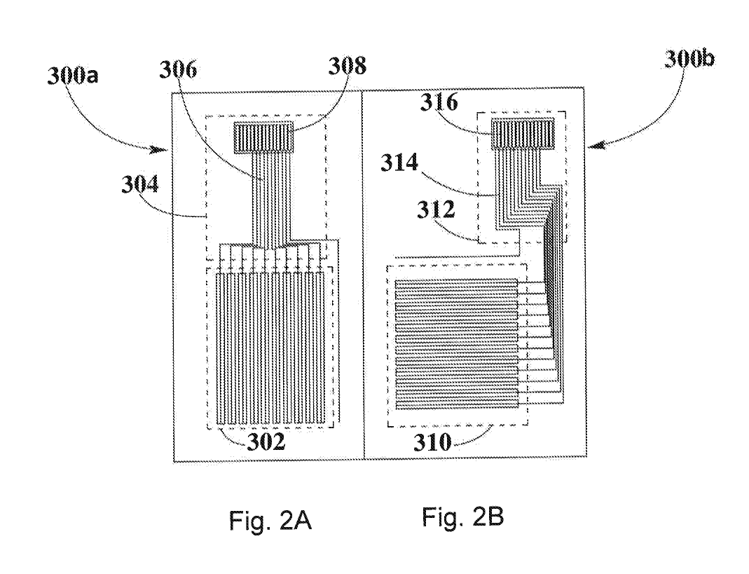

FIG. 2A depicts the top views at 300a of a first to be printed on one side of thin flexible transparent substrates. A first pattern 300a may be printed on one side of a first flexible substrate, including lines 302 that may constitute the Y oriented segment of an X-Y grid, and tail 304 comprising electrical leads 306 and electrical connectors 308. FIG. 2B depicts an embodiment of a second pattern 300b which may be printed on one side of a second flexible substrate, comprising a plurality of lines 310 that may constitute the X oriented segment of an X-Y grid (not pictured) and tail 312 comprising electrical leads 314 and electrical connectors 316.

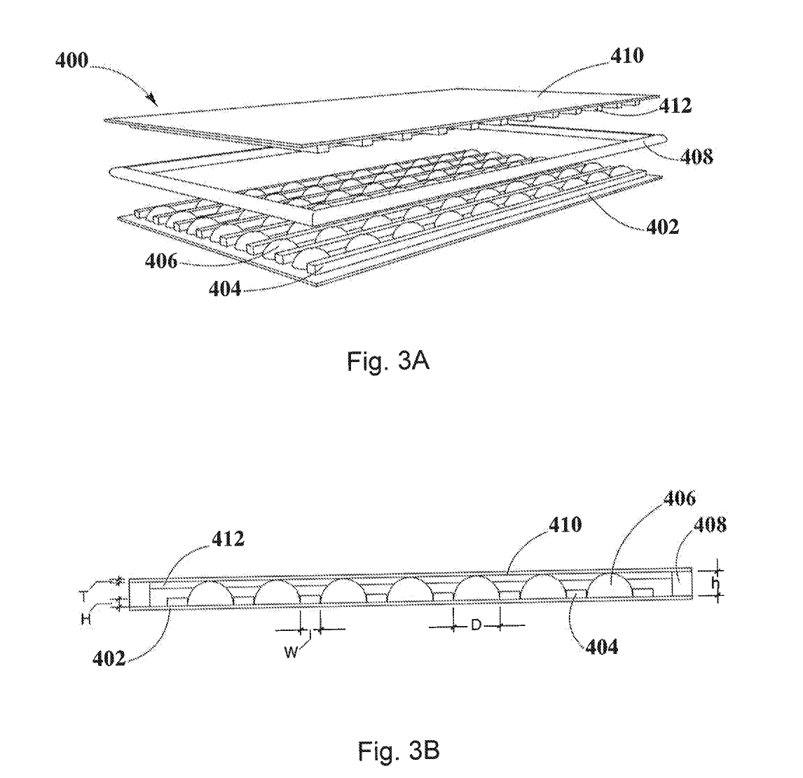

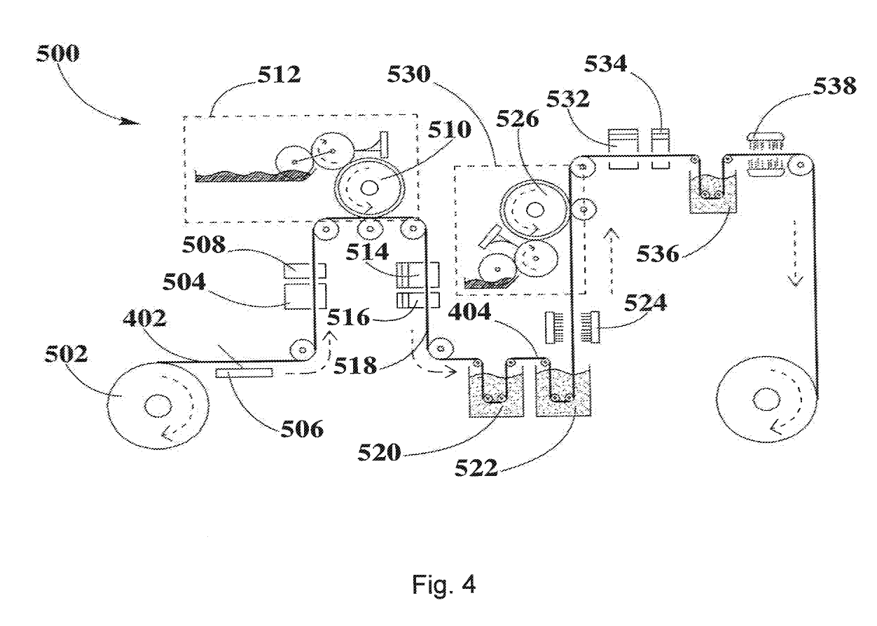

FIGS. 3A and 3B depict an isometric view and a cross sectional view of a resistive touch sensor circuit. In FIG. 4A, the resistive touch sensor circuit 400 may comprise a first set, which may also be referred to as a first plurality, of conductive lines 404 and a plurality of microstructural insulating protrusions 406. The plurality of microstructural insulating protrusions 406 may be referred to as spacer dots, spacer microstructures, or spacers, and are attached to a first substrate 402. In addition, a second set of conductive lines 412, which may also be referred to as a second plurality of lines, may be attached to second substrate 410. The first and the second sets of conductive lines, at 402 and 412, may comprise at least one line of a plurality of lines. In an embodiment, the circuit 400 comprises an adhesive promoting agent 408, bonding first substrate 402, and second substrate 410. FIG. 3B is a cross-sectional view of an assembled resistive touch sensor circuit wherein the plurality of conductive lines 404 with height “H” and width “W” are disposed on the first substrate 402. The plurality of microstructural insulating protrusions 406 with height “h” and diameter “D” are disposed in an alternating fashion with each line of the plurality of conductive lines 404, and a second substrate 410 is disposed on top of the first substrate 402. The second substrate comprises a second plurality of conductive lines 412 and the adhesive promoting agent 408 disposed between the first substrate 402 and the second substrate 410.

In some embodiments, suitable materials for the first and the second sets of conductive lines may include copper (Cu), silver (Ag), gold (Au), nickel (Ni), tin (Sn) and Palladium (Pd) among others. Depending on the resistivity of the materials used for the circuit, it may have different response times and power requirements. In some embodiments the circuit lines may have a resistivity between 0.005 Micro-ohms and 500 Ohms per square and response times in a range between nanoseconds and picoseconds. In some embodiments with the above metal configuration, circuits consuming 75% less power than those using ITO (Indium Tin Oxide) may be achieved. In one particular embodiment the width (W) of the printed electrodes varies from 5 to 10 microns with a tolerance of +/−10%. The spacing (D) between the lines may vary from about 100 microns to 5 mm. Spacing D and width W are functions of the size of the display and desired resolution of the sensor. Height H may range from about 150 nanometers to about 6 microns. Height (h) of adhesive promoting agent 408 and spacer dots 406 may be of 500 nanometers or more, depending on the height H of the first and second sets of conductive lines. Thin first substrate 402 and second substrate 410 may exhibit thickness T between 1 micron and 1 millimeter and a preferred surface energy from 20 dynes/cm to 90 dynes/cm.

FIG. 4 depicts a manufacturing method 500, which is a method to fabricate a touch sensor in accordance with various embodiments of the invention. Following the process, an elongated, transparent, flexible, thin first substrate 402 is placed on unwind roll 502. Various transparent flexible available substrates in the market may be used. In some embodiments, PET (polyethylene terephthalate), polyester and polycarbonate are transparent materials that may be used. The thickness of first substrate 402 is chosen as to avoid excessive stress during flexing of the touch sensor and, in some embodiments, to improve optical transmissivity. The thickness of first substrate 402 may also be chosen to be thick enough as to not jeopardize the continuity of this layer or its material properties during the manufacturing process. In an embodiment, a thickness between 1 micron and 1 millimeter may be suitable. The first substrate 402 is transferred, via any known roll to roll handling method, from an unwind roll 502 to first cleaning system 504. As a roll to roll process involves a flexible substrate, the alignment between the substrate and the flexographic master plate 510 may be somewhat challenging. Given that printing high resolution lines may be a focus of the process, precision in maintaining the right alignment may be preferable. In an embodiment, a positioning cable 506 may be used to maintain alignment between these two features, in other embodiments other means may be used for this purpose. In some embodiment, as first cleaning system 504 may comprise a high electric field ozone generator. The ozone generated may then be used to remove impurities, for example, oils or grease, from the first substrate 402.

In an embodiment, the first substrate 402 may go through a second cleaning system 508. In this particular embodiment, the second cleaning system 508 may comprise a web cleaner. After the cleaning stages 506 and 508, the first substrate 402 may undergo a first printing process 510 where a microscopic pattern is printed on a first side of first substrate 402. The microscopic pattern is imprinted by a master plate 510 using, for example, a UV curable ink that may have a viscosity between 200 and 2000 cps or more. In an embodiment, the microscopic pattern may comprise lines having a width, for example, between 1 and 20 microns or more. In an embodiment, this pattern may be similar to the first pattern shown in FIG. 3. In some embodiments, the amount of ink transferred from master plate 510 to the substrate 402 may be regulated by high precision metering system 512 and depends on the speed of the process, ink composition and patterns shape and dimension. In an embodiment, the speed of the machine may vary from 20 feet per minute (fpm) to 750 fpm. In an alternate embodiment, the speed of the machine may vary from 50 fpm to 200 fpm.

In an embodiment, the ink may contain plating catalysts. The first printing process 510 may be followed by a curing step 514. The curing may comprise, for example, an ultraviolet light curing process 514 with target intensity. In an embodiment, the target intensity may be from about 0.5 mW/cm² to about 50 mW/cm² and wavelength from about 240 nm to about 580 nm. In addition the curing may comprise an oven heating 516 module that applies heat within a temperature range of about 20° C. to about 125° C. In some embodiment, other curing processes such as a heat treatment may be employed in addition to a UV cure or as an alternative. After the curing step 510, first patterned lines 518 are formed on top of the first substrate 402.

In an embodiment, the first substrate 402 may be exposed to electroless plating 520 subsequent to printing the microscopic pattern on the first side of the substrate. A layer of conductive material 520 may be deposited or disposed on the microscopic pattern created 518. In an embodiment, this may be accomplished by submerging first patterned lines 518 of the first substrate 402 into a plating tank 520. In an embodiment, the plating tank may contain compounds of copper or other conductive materials in a dissolved state at a temperature range between 20° C. and 90° C. (e.g., 40° C.). In an embodiment, after plating 520, a first set of conductive lines may have formed on top of first substrate 402. In an embodiment, deposition rate of the electroless plating 520 may be 10 nanometers per minute and within a thickness of about 0.001 microns to about 100 microns. The deposition rate may depend on the speed of the web and according to the application. This electroless plating process may not require the application of an electrical current and may only plate the patterned areas containing plating catalysts that were previously activated by the exposition to UV radiation during the curing process 514.

In an embodiment, nickel may be used as the plating metal. In another embodiment, the copper plating bath may include powerful reducing agents in it, such as formaldehyde, borohydride or hypophosphite, which cause the plating to occur. In an embodiment, plating thickness may be uniform compared to electroplating due to the absence of electric fields. Although electroless plating may generally be more time consuming than electrolytic plating, electroless plating may be well suited for parts with complex geometries and/or many fine features.

In some embodiments a washing process 522 follows electroless plating at block 520. After the plating process 520, a first substrate 402 may be cleaned by being submerged into a cleaning tank that contains water at room temperature and then preferably goes through a drying step 524 in which it is dried by the application of air at room temperature. In another embodiment, a passivation step in, for example, a pattern spray may be added after the drying step to prevent any dangerous or undesired chemical reaction between the conductive materials and water.

This may be followed by the creation of spacer dots 406 shown in FIG. 3. A pattern of microstructural spacer dots is then printed on the first side of first substrate 402. The pattern may be printed by a second master plate 526 using UV curable ink that may have a viscosity between 200 and 2000 cps or higher. In some embodiments the amount of ink transferred from second master plate 526 to substrate 402 is regulated by high precision metering system 530 and depends on the speed of the process, ink composition and patterns shape and dimension.

In an embodiment, the ink used to print spacer dots 406 may be comprised of organic-inorganic nanocomposites utilizing methyl tetraethylorthosilicate or glycidopropyltrimetoxysilane as network formers hydrolyzed using hydrochloric acid. Silica sols, silica powders, ethyl cellulose and hydroxypropyl may be utilized as additives to adjust viscosity. The ink may also comprise a commercially available photoinitiator, such as Cyracure, Flexocure or Doublecure, allowing the use of ultraviolet light curing. In some embodiments spacer dots 406 may be enhanced optically by nano-particle metal oxides and pigments such as titanium dioxide (TiO₂), barium titanium dioxide (BaTiO), silver (Ag), nickel (Ni), molybdenum (Mo) and platinum (Pt). The index of refraction of the spacer dots preferably will match optically the index of refraction of the first set of conductive lines 404. Nano-particles may also be used to adjust the viscosity of the ink. Furthermore, the shrinkage during curing may be reduced by the incorporation of nanoparticle leads to the ink.

Following the spacer dot printing process 526, the first substrate 402 may go through a second curing step, comprising ultraviolet light curing 532 with an intensity about from 0.5 mW/cm² to 20 mW/cm² and/or oven drying 534 at a temperature approximately between 20° C. and 150° C. In an embodiment, spacer dots 406 may have a radius between 80 microns and 40 microns and a height between 500 nanometers and 15 microns. In an embodiment, after the spacer dot printing 526, the first substrate 402 may go through a second washing process 536. The second washing process 536 may be performed, for example, using known conventional washing techniques, and then first substrate 402 may be dried using air at room temperature in a second drying step 538.

In a parallel process, following similar steps as in 502-538, the second set of conductive lines 412 shown in FIG. 3 may be created on one side of second substrate 410. In an embodiment, a different set of master plates is used to create the conductive lines on a second side of the first substrate. In another embodiment, a different set of master plates may be used to create the second set of conductive lines on the first side of the first substrate adjacent to the first set of lines, and, in an embodiment, this second set of lines may be along a different plane than the first set of lines. For example, the first set of lines may be printed along the x-axis of the first substrate and the second set of lines may be printed along the y-axis. Alternatively, spacer dots may be printed in addition to or instead of the blocks printed 526 on second substrate 410 according to the methods and specifications stated above.

In an embodiment, a resistive touch sensor may be assembled using the two printed patterns. First a layer of adhesive promoting agent may be applied 408 on a first substrate 402 surrounding the first set of conductive lines 404. The adhesive layer may have a layer thickness of more than 500 nanometers. Then second substrate 410 carrying second set of conductive lines 412 may be bonded to substrate 402. In an embodiment, the first substrate 402 may be bonded to the second substrate 410 in such a way that both conductive patterns are aligned, facing each other and separated by the small gap created by spacer dots 406 and adhesive promoting agent 408. The resulting structure would be an X-Y matrix resistive touch sensor, where each of the intersections of the first and second sets of conductive lines forms a normally open push button switch, as illustrated in FIG. 4. In an embodiment, if both patterns are printed on the same side of the first substrate, the substrate may need to be cut and/or trimmed at block

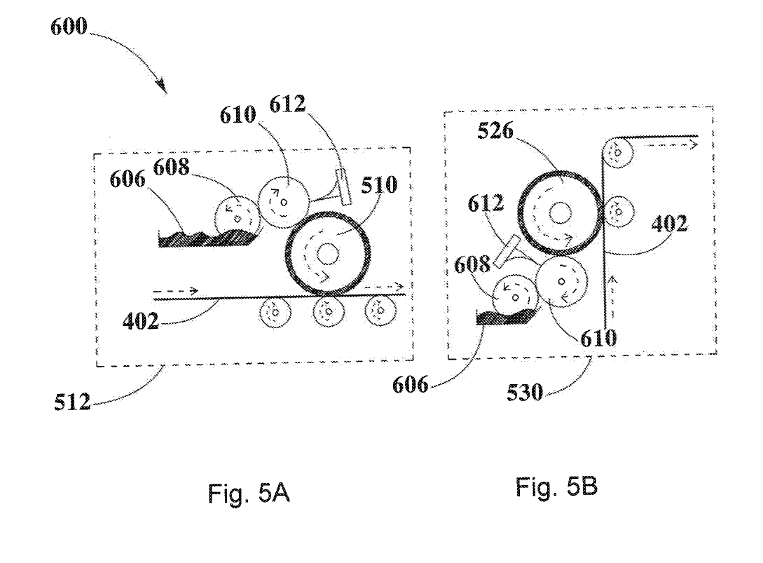

FIGS. 5A and 5B depict embodiments of a high precision metering system. In FIG. 5A, system 600 is a high precision metering system 512 and in FIG. 5B there is a high precision metering system 530. Both high precision metering systems 512 and 530 may control the exact amount of ink that is transferred to first substrate 402 by master plate 510 and second master plate 526 as described in both printing steps of manufacturing method 500 in FIG. 4. In an embodiment, the system 512 in FIG. 5A may be used for printing a first plurality of patterned lines 518 on the substrate 402 and the system in FIG. 5B may be used for printing spacer dots 406 on, for example, the substrate 402. The systems in FIGS. 5A and 5B comprise ink pans 606, transfer rolls 608, anilox rollers 610, doctor blades 612 and the master plates at 510, 526. In both FIGS. 5A and 5B, a portion of the ink contained in ink pan 606 is transferred to anilox rollers 610, possibly constructed of a steel or aluminum core which may be coated by an industrial ceramic whose surface contains millions of very fine dimples, known as cells. Depending on the design of the printing process, anilox rollers 610 may be either semi-submersed in ink pans 606 or comes into contact with a transfer roll 610. Doctor blades 612 may be used to scrape excess ink from the surface leaving just the measured amount of ink in the cells. The roll then rotates to contact with the flexographic printing plates (master plate 510 and second master plate 526) which receive the ink from the cells for transfer to first substrate 402. The rotational speed of the printing plates should preferably match the speed of the web, which may vary between 20 fpm and 750 fpm.

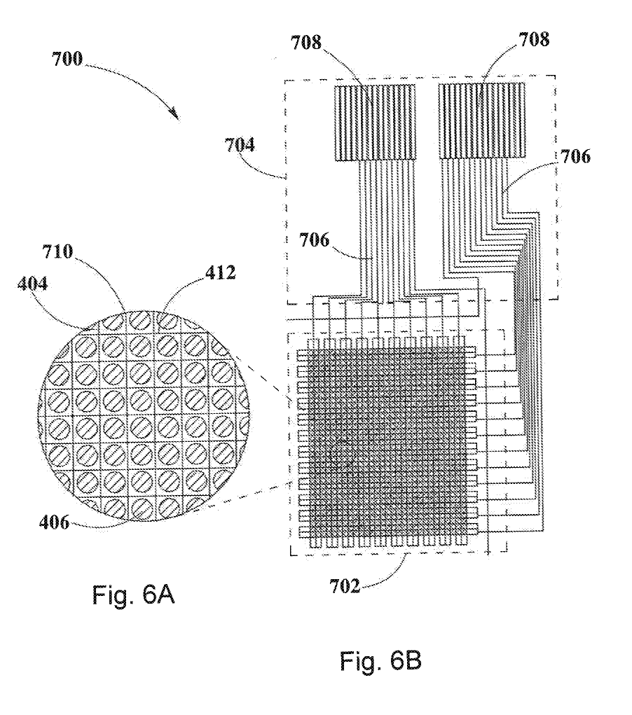

FIGS. 6A and 6B are illustrations of embodiments of a top view of an assembled resistive circuit printed thin flexible transparent substrates. In FIG. 6B, the top view 700 comprises a plurality of conductive grid lines 702 and a tail 704 comprising a plurality of electrical leads 706 and a plurality of electrical connectors 708. These sets of conductive lines (discussed below in FIG. 6A) may conform an x-y grid, that enables the recognition of the point in where the user has interacted with the sensor (not pictured). In an embodiment, this grid may have one more sets of 16×9 conductive lines. In an embodiment, the size range for these sets of conductive lines may vary from 2.5 mm by 2.5 mm to 2.1 m by 2.1 m. At least one set of conductive lines corresponding to the Y axis and spacer dots may have been printed on a first substrate and at least one set of conductive lines corresponding to the X axis may have been printed on a second substrate. FIG. 6A shows an exploded view 710 of an embodiment in which a plurality of spacer dots 406 and the X-Y grid, formed by a first set conductive lines 404 and a second set of conductive lines 412.

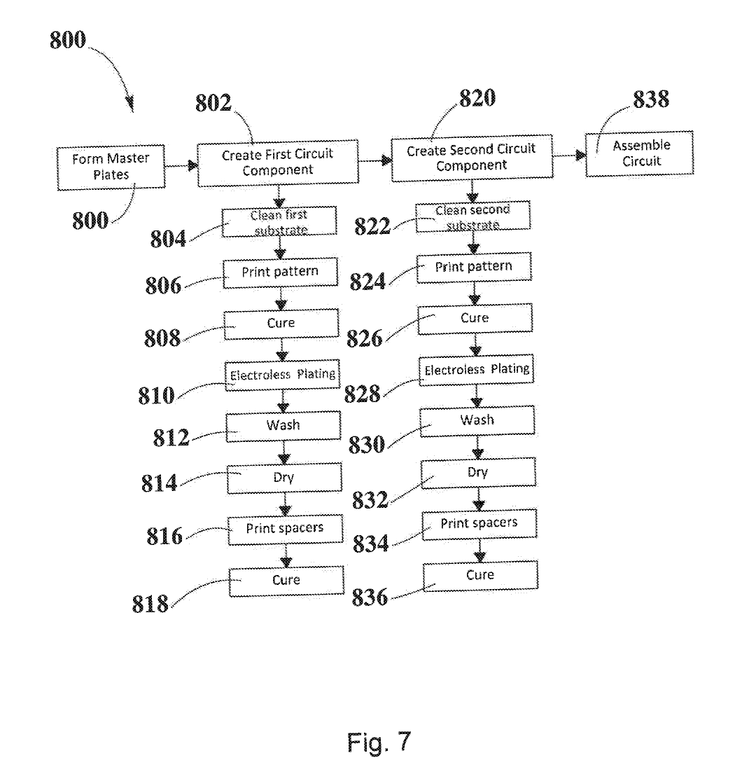

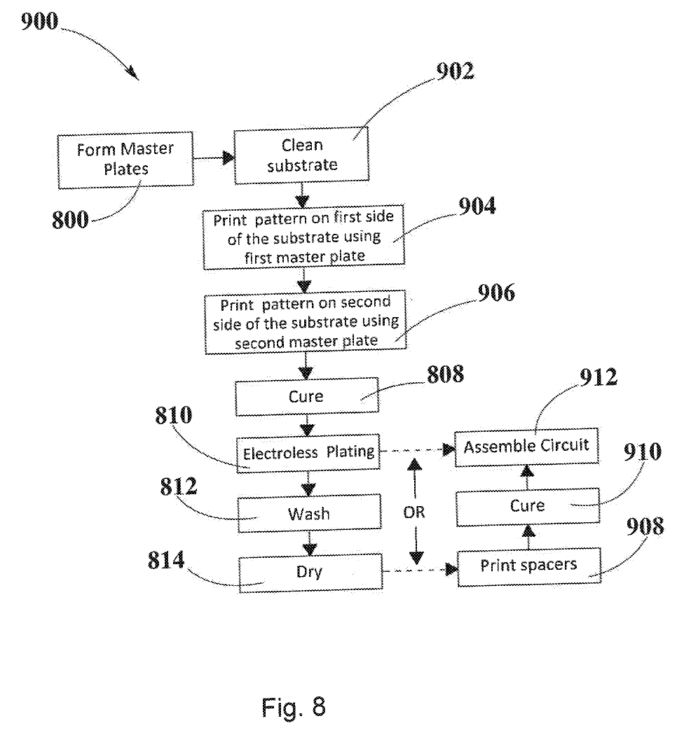

FIG. 7 illustrates an embodiment of a method of manufacture of a resistive touch sensor circuit. At 800, at least one master plate is formed, for example, using the system disclosed in FIG. 1. After the at least one master plate is formed, the first circuit component may be created 802. A first substrate is cleaned at cleaning station 804 by, for example, a plasma cleaning process, an elastomeric cleaning process, or an ultrasonic cleaning process, high electric ozone field generator, web cleaning, or water wash. Subsequent to cleaning, a first pattern which may comprise a set of microscopic conductive lines, which may also be referred to as a microstructural or microscopic pattern, is printed by a first master plate on a first side of the first substrate at block 806. The printing of the first set of conductive lines may use conductive material, wherein the conductive material may comprise at least one of copper (Cu), silver (Ag), gold (Au), nickel (Ni), tin (Sn), and Palladium (Pd). At curing station 808 the substrate is cured, for example, by at least one of an infrared heater, ultraviolet heater, or a convection heater. At plating station 810 electroless plating is performed on the first substrate. The substrate may be washed at washing station 812 and dried at drying station 814. At printing station 816, a set of spacer microstructures may be printed on the same area of the substrate where the first microstructural pattern was printed. Turning back to FIG. 4, the ink used to print spacer dots 406 may be comprised of organic-inorganic nanocomposites utilizing methyl tetraethylorthosilicate or glycidopropyltrimetoxysilane as network formers hydrolyzed using hydrochloric acid. Silica sols, silica powders, ethyl cellulose and hydroxypropyl may be utilized as additives to adjust viscosity. The ink may also comprise a commercially available photoinitiator, such as Cyracure, Flexocure or Doublecure, allowing the use of ultraviolet light curing. In some embodiments spacer dots 406 may be enhanced optically by nano-particle metal oxides and pigments such as titanium dioxide (TiO₂), barium titanium dioxide (BaTiO), silver (Ag), nickel (Ni), molybdenum (Mo) and platinum (Pt). At curing station 820 the first substrate may be cured.

In some embodiments, a second master plate may be formed 800, the second circuit component may be created by process 822. A first substrate is cleaned at cleaning station 824 by, for example, a plasma cleaning process, an elastomeric cleaning process, or an ultrasonic cleaning process, high electric ozone field generator, web cleaning, or water wash. Subsequent to cleaning, a second microstructural pattern which may comprise a second set of conductive lines is printed by a second master plate on a first side of the second substrate at printing station 826. The second set of microstructural patterns may be printed with the same ink as the first set or, an embodiment, with different ink. In an embodiment, the first and/or the second set of conductive lines may be printed using more than one flexo-master. The printing of the second set of conductive lines may use conductive material, wherein the conductive material comprises at least one of copper (Cu), silver (Ag), gold (Au), nickel (Ni), tin (Sn), and Palladium (Pd). At curing station 828 the substrate is cured, for example, by at least one of an infrared heater, ultraviolet heater, or a convection heater. At plating station 830 electroless plating is performed on the first substrate. The substrate may be washed at washing station 832 and dried at drying station 834. At printing station 836, a set of spacer microstructures may be printed on the same area of the substrate where the first microstructural pattern was printed. Turning back to FIG. 4, the ink used to print spacer dots 406 may be comprised of organic-inorganic nanocomposites utilizing methyl tetraethylorthosilicate or glycidopropyltrimetoxysilane as network formers hydrolyzed using hydrochloric acid. Silica sols, silica powders, ethyl cellulose and hydroxypropyl may be utilized as additives to adjust viscosity. The ink may also comprise a commercially available photoinitiator, such as Cyracure, Flexocure or Doublecure, allowing the use of ultraviolet light curing. In some embodiments spacer dots 406 may be enhanced optically by nano-particle metal oxides and pigments such as titanium dioxide (TiO₂), barium titanium dioxide (BaTiO), silver (Ag), nickel (Ni), molybdenum (Mo) and platinum (Pt). At curing station 838 the first substrate may be cured. The circuit may be assembled 840, in some embodiments, the circuit is assembled by aligning the first and the second substrates. In some embodiments, aligning comprises facing the first microstructural pattern of the first substrate towards the second microstructural pattern of the second substrate. In an embodiment, an adhesive is used to assemble the circuit, wherein the adhesive layer may be up to 500 nm thick. In an embodiment, the first substrate and/or the second substrate may be cut or trimmed prior to assembly. In an embodiment, the first or the second substrate may be passivated after it is dried at drying stations 814 and/or 834.

FIG. 8 is an embodiment of a method of manufacture of a resistive touch sensor circuit. A substrate may be cleaned at cleaning station 902 by, for example, at least one of a plasma cleaning process, an elastomeric cleaning process, or an ultrasonic cleaning process, high electric ozone field generator, web cleaning, or water wash. Subsequent to cleaning, a first microstructural pattern which may comprise conductive lines may be printed at a printing station 904 by a first master plate on a first side of the first substrate. A second pattern may be printed at printing station 906, for example, by using a second master plate. The first or the second set of conductive line patterns may be printed using one flexo-master or more than one flexo-masters. The first and the second sets of patterns of conductive lines may be printed using the same ink or different inks. In an embodiment, the printing of the first and/or the second sets of conductive lines may use conductive material, wherein the conductive material may comprise at least one of copper (Cu), silver (Ag), gold (Au), nickel (Ni), tin (Sn), and Palladium (Pd). At curing station 808 the substrate is cured, for example, by at least one of an infrared heater, ultraviolet heater, or a convection heater. At plating station 810 electroless plating is performed on the substrate. The substrate may be assembled subsequent to electroless plating at assembly station 912. In an alternate embodiment, the substrate may be washed at washing station 812 and dried at drying station 814 prior to printing of spacers at printing station 908. At printing station 908, a set of spacers may be printed on one or both of the patterns made by the first and the second master plates at printing stations 904 and 906. In an embodiment, the substrate may be cured at curing station 910 subsequent to assembly at assembly station 912. In an embodiment, the substrate may be cut and/or trimmed prior to assembly.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

1. A method for manufacturing a resistive touch sensor circuit comprising:
creating a first circuit component, wherein creating the first circuit component comprises:
printing, by a flexographic printing process using a first master plate and a first ink, a first pattern on a first side of the first substrate;
curing the substrate;
depositing, by an electroless plating process, a first conductive material on the first side of the first substrate;
printing, by the flexographic printing process using a second master plate and a second ink, a first plurality of spacer microstructures; and
subsequently curing the substrate;
creating a second circuit component comprising:
printing, by the flexographic printing process using a third master plate and a third ink, a second pattern on a first side of the second substrate;
curing the substrate;
depositing, by the electroless plating process, a second conductive material on the first side of the second substrate;
printing, by the flexographic printing process using a fourth master plate and a fourth ink, a second plurality of spacer microstructures; and
subsequently curing the substrate.

2. The method of claim 1, further comprising applying a first layer of an adhesive on the first substrate around the first pattern.

3. The method of claim 2, wherein a layer thickness of the adhesive is at least 500 nanometers.

4. The method of claim 1, wherein the first ink and the second ink are different.

5. The method of claim 1, further comprising assembling the first and the second components, wherein assembling the circuit further comprises aligning the first and the second substrates, wherein aligning comprises facing the first pattern of the first substrate towards the second pattern of the second substrate.

6. The method of claim 5, further wherein assembling the circuit comprises an X-Y matrix resistive touch sensor comprising a plurality of intersections of the first and the second patterns, wherein each of the plurality of intersections of the first and second patterns forms a normally open push button switch.

7. The method of claim 1, wherein the first and the second conductive materials are different.

8. The method of claim 1, wherein the second ink and the fourth ink may be enhanced optically by at least one of a plurality of nano-particle metal oxides and pigments, wherein the plurality of nano-particle metal oxides and pigments comprise titanium dioxide (TiO₂), barium titanium dioxide (BaTiO₃), silver (Ag), nickel (Ni), molybdenum (Mo), and platinum (Pt).

9. The method of claim 1, wherein the second ink and the fourth ink may comprise at least one network former, wherein the at least one network former comprises organic-inorganic nanocomposites utilizing methyl tetraethylorthosilicate and glycidopropyltrimetoxysilane.

10. A method for manufacturing a resistive touch sensor circuit comprising:
cleaning a substrate, wherein a plane of the substrate comprises an X and a Y axis;
printing, by a flexographic process using a first master plate and a first ink, a first pattern on a first side of the substrate,
printing, by a flexographic process using a second master plate and the first ink, a second pattern on the first side of the substrate;
curing the substrate;
depositing, by an electroless plating process, a conductive material on the first side of the substrate,
printing, by a flexographic process using a third master plate and a second ink, a plurality of spacer microstructures on the same area of the substrate where the first pattern was printed;
subsequently, curing the substrate.

11. The method of claim 10, wherein the first pattern is printed along the x-axis and the second pattern is printed adjacent to the first pattern along the y-axis.

12. The method of claim 10, wherein the conductive material comprises at least one of copper (Cu), silver (Ag), gold (Au), nickel (Ni), tin (Sn), and Palladium (Pd).

13. The method of claim 10, wherein an index of refraction of the spacer dots matches optically an index of refraction of the first pattern.

14. The method of claim 10, further comprising assembling the first and the second substrate, wherein assembling the circuit further comprises aligning the first and the second substrates, wherein aligning comprises facing the first pattern of the first substrate towards the second pattern of the second substrate.

15. The method of claim 10, wherein the first ink and the second ink contain at least one plating catalyst of a plurality of plating catalysts.

16. A method for manufacturing a resistive touch sensor circuit comprising:
printing, using a first master plate and a first ink, a first pattern on a first side of the substrate;
printing, by a flexographic printing process using a second master plate and a second ink, a second pattern on the first side of the substrate, wherein the first and the second patterns are printed adjacent to each other along a surface plane of the substrate;
curing the substrate;
depositing, by an electroless plating process, a conductive material on the first, patterned side of the substrate.

17. The method of claim 16, wherein the substrate is cleaned by at least one of a plasma cleaning process, an elastomeric cleaning process, and an ultrasonic cleaning process.

18. The method of claim 16, wherein the substrate is passivated.

19. The method of claim 16, wherein the conductive material comprises at least one of copper (Cu), silver (Ag), gold (Au), nickel (Ni), tin (Sn), and Palladium (Pd).

20. The method of claim 16, wherein the first ink and the second ink are different.
